(19) United States
(12) Patent Application Publication
(10) Pub. No.: US 2010/0025743 A1
(43) Pub. Date: Feb. 4, 2010

(54) TRANSISTOR WITH EMBEDDED SI/GE MATERIAL HAVING ENHANCED BORON CONFINEMENT

(76) Inventors: Jan Hoentschel, Dresden (DE); Maciej Wiatr, Dresden (DE); Vassilios Papageorgiou, Austin, TX (US)

Correspondence Address: WILLIAMS, MORGAN & AMERSON, 10333 RICHMOND, SUITE 1100, HOUSTON, TX, 77042, US

(21) Appl. No.: 12/503,340

(22) Filed: Jul. 15, 2009

(30) Foreign Application Priority Data
Jul. 31, 2008 (DE) 10 2008 035 806.1

(51) Int. Cl. H01L 29/78; H01L 21/336

(52) U.S. Cl. 257/288; 438/299; 257/E29.255; 257/E21.431

(57) ABSTRACT

By incorporating a diffusion hindering species at the vicinity of PN junctions of P-channel transistors comprising a silicon/germanium alloy, diffusion related non-uniformities of the PN junctions may be reduced, thereby contributing to enhanced device stability and increased overall transistor performance. The diffusion hindering species may be provided in the form of carbon, nitrogen and the like.

### BACKGROUND OF THE INVENTION

1. Field of the Invention

Generally, the present disclosure relates to the fabrication of integrated circuits, and, more particularly, to the formation of transistors having strained channel regions by using embedded silicon/germanium (Si/Ge) to enhance charge carrier mobility in the channel regions of the transistors.

2. Description of the Related Art

The fabrication of complex integrated circuits requires the provision of a large number of transistor elements, which represent the dominant circuit element for designing circuits. For example, several hundred millions of transistors may be provided in presently available complex integrated circuits. Generally, a plurality of process technologies are currently practiced, wherein, for complex circuitry, such as microprocessors, storage chips and the like, CMOS technology is currently the most promising approach due to the superior characteristics in view of operating speed and/or power consumption and/or cost efficiency. In CMOS circuits, complementary transistors, i.e., P-channel transistors and N-channel transistors, are used for forming circuit elements, such as inverters and other logic gates to design highly complex circuit assemblies, such as CPUs, storage chips and the like. During the fabrication of complex integrated circuits using CMOS technology, millions of transistors, i.e., N-channel transistors and P-channel transistors, are formed on a substrate including a crystalline semiconductor layer. A MOS transistor, or generally a field effect transistor, irrespective of whether an N-channel transistor or a P-channel transistor is considered, comprises so-called PN junctions that are formed by an interface of highly doped drain and source regions with an inversely or weakly doped channel region disposed between the drain region and the source region. The conductivity of the channel region, i.e., the drive current capability of the conductive channel, is controlled by a gate electrode formed in the vicinity of the channel region and separated therefrom by a thin insulating layer. The conductivity of the channel region, upon formation of a conductive channel due to the application of an appropriate control voltage to the gate electrode, depends on the dopant concentration, the mobility of the charge carriers and, for a given extension of the channel region in the transistor width direction, on the distance between the source and drain regions, which is also referred to as channel length. Thus, the reduction of the channel length, and associated therewith the reduction of the channel resistivity, is a dominant design criterion for accomplishing an increase in the operating speed of the integrated circuits.

The continuing shrinkage of the transistor dimensions, however, involves a plurality of issues associated therewith that have to be addressed so as to not unduly offset the advantages obtained by steadily decreasing the channel length of MOS transistors. For example, highly sophisticated dopant profiles, in the vertical direction as well as in the lateral direction, are required in the drain and source regions to provide low sheet and contact resistivity in combination with a desired channel controllability. Moreover, the gate dielectric material may also be adapted to the reduced channel length in order to maintain the required channel controllability. However, some mechanisms for maintaining a high channel controllability may also have a negative influence on the charge carrier mobility in the channel region of the transistor, thereby partially offsetting the advantages gained by the reduction of the channel length.

Since the continuous size reduction of the critical dimensions, i.e., the gate length of the transistors, necessitates the adaptation and possibly the new development of highly complex process techniques, and may also contribute to less pronounced performance gain due to mobility degradation, it has been proposed to enhance the channel conductivity of the transistor elements by increasing the charge carrier mobility in the channel region for a given channel length, thereby enabling a performance improvement that is comparable with the advance to a technology standard requiring extremely scaled critical dimensions, while avoiding or at least postponing many of the process adaptations associated with device scaling.

One efficient mechanism for increasing the charge carrier mobility is the modification of the lattice structure in the channel region, for instance by creating tensile or compressive stress in the vicinity of the channel region to produce a corresponding strain in the channel region, which results in a modified mobility for electrons and holes, respectively. For example, creating tensile strain in the channel region for a standard crystallographic configuration of the active silicon material, i.e., a (100) surface orientation with the channel length aligned to the <110> direction, increases the mobility of electrons, which in turn may directly translate into a corresponding increase in the conductivity. On the other hand, compressive strain in the channel region may increase the mobility of holes, thereby providing the potential for enhancing the performance of P-type transistors. The introduction of stress or strain engineering into integrated circuit fabrication is an extremely promising approach, since strained silicon may be considered as a “new” type of semiconductor material, which may enable the fabrication of fast powerful semiconductor devices without requiring expensive semiconductor materials, while many of the well-established manufacturing techniques may still be used.

Consequently, it has been proposed to introduce, for instance, a silicon/germanium layer material next to the channel region to induce a compressive stress that may result in a corresponding strain. The transistor performance of P-channel transistors may be considerably enhanced by the introduction of stress-creating materials next to the channel region. For this purpose, a strained silicon/germanium material may be formed in the drain and source regions of the transistors, wherein the compressively strained drain and source regions create uniaxial strain in the adjacent silicon channel region. When forming the Si/Ge material, the drain and source regions of the PMOS transistors are selectively recessed to form cavities, while the NMOS transistors are masked, and subsequently the silicon/germanium material is selectively formed in the PMOS transistor by epitaxial growth.

Although the technique has significant advantages in view of performance gain of P-channel transistors, and thus of the entire CMOS device, it turns out, however, that, in advanced semiconductor devices including a large number of transistor elements, an increased variability of device performance may be observed, which may be associated with the above-described technique for incorporating a strained silicon-germanium alloy in the drain and source regions of P-channel transistors, as will be described in more detail with reference to FIGS. 1a and 1b.

FIG. 1a schematically illustrates a cross-sectional view of a conventional semiconductor device 100 comprising an advanced P-channel transistor 150, the performance of which may be increased on the basis of a strained silicon/germanium alloy, as explained above. The semiconductor device 100 comprises a substrate 101, such as a silicon substrate, which may have formed thereon a buried insulating layer 102. Furthermore, a crystalline silicon layer 103 is formed on the buried insulating layer 102, thereby representing a silicon-on-insulator (SOI) configuration. An SOI configuration may be advantageous in view of overall transistor performance since, for instance, the parasitic junction capacitance of the transistor 150 may be reduced compared to a bulk configuration, i.e., a configuration in which a thickness of the silicon layer 103 may be significantly greater than a vertical extension of the transistor 150 into the layer 103. The transistor 150 may be formed in and above an “active” region, generally indicated as 103A, which represents a portion of the semiconductor layer 103, which may be bordered by respective isolation structures (not shown), such as shallow trench isolations and the like. The transistor 150 comprises a gate electrode structure 151 which may be understood as a structure including a conductive electrode material 151A, representing the actual gate electrode, which may be formed on a gate insulation layer 151B of the structure 151, thereby electrically isolating the gate electrode material 151A from a channel region 152 located within the active region 103A. Furthermore, the gate electrode structure 151 may comprise a sidewall spacer structure 151C which may include one or more spacer elements, possibly in combination with etch stop liners, depending on the overall device requirements. Moreover, the transistor 150 may comprise drain and source regions 153, which may be defined by an appropriate dopant species, such as boron, which may, in combination with the channel region 152 and any further portion of the active region 103A positioned between the drain and source regions 153, define PN junctions 153P, which may significantly affect the overall behavior of the transistor 150. For example, the degree of overlap of the drain and source regions 153 with the gate electrode 151A may determine the effective channel length and may thus also determine the capacitive coupling between the gate electrode 151A and each of the drain and source regions 153. Similarly, the effective length of the PN junctions 153P may finally determine the parasitic junction capacitance of the transistor 150, which may also affect the finally achieved performance of the transistor 150. In order to appropriately adjust the overall transistor characteristics, frequently, regions of increased counter doping levels 154 may be provided adjacent to the drain and source regions 153 at specified positions within the active region 103A, which may also be referred to as halo regions. For example, the adjustment of punch through behavior, threshold voltage and the like may be accomplished on the basis of complex dopant profiles in the active region 103A, by appropriately creating the counter doped region 154 in combination with providing a desired concentration profile in the drain and source regions 153. Furthermore, as previously discussed, the transistor 150 may comprise a silicon/germanium alloy 155 in the drain and source regions 153, wherein the silicon/germanium alloy may have a natural lattice constant that is greater than the lattice constant of the surrounding silicon material in the active region 103A. Consequently, upon forming the silicon/germanium alloy on the basis of a template material having a reduced lattice constant compared to the natural lattice constant of the material 155, a strained state may be generated and a corresponding strain may also be induced in the channel region 152. As previously explained, for a standard crystallographic orientation of the material of the semiconductor layer 103, a uniaxial compressive strain component, i.e., a strain component along the horizontal direction in FIG. 1a, may be generated and may result in increased hole mobility, thereby also enhancing overall performance of the transistor 150.

The semiconductor device 100 as shown in FIG. 1a may be formed on the basis of the following conventional process strategies. The active region 103A may be defined on the basis of isolation structures which may be formed by using well-established photolithography, etch, deposition and planarization techniques. Thereafter, the basic doping level in the corresponding active regions 103A may be established, for instance, by implantation processes. Next, the gate electrode structure 151, without the spacer structure 151C, may be formed by using complex lithography and patterning regimes to obtain the gate electrode 151A and the gate insulation layer 151B. It should be appreciated that the patterning process for the gate electrode structure 151 may also include a patterning of an appropriate cap layer (not shown), which may be used as a mask during the further processing for forming the silicon/germanium material 155. Next, appropriate sidewall spacers may be formed on sidewalls of the gate electrode structure 151 so as to encapsulate, in combination with the cap layer, the gate electrode 151A and the gate insulation layer 151B during the further processing. At the same time, an appropriate mask layer may be formed above other transistor areas in which the strained silicon/germanium material 155 may not be required. After appropriately masking the gate electrode 151A and other device areas, an etch process may be performed in order to obtain a cavity within the active region 103A adjacent to the gate electrode 151A. The size and shape of the corresponding cavity may be adjusted on the basis of process parameters of the corresponding etch process, that is, a substantially isotropic etch behavior may result in a corresponding under-etching of a sidewall spacer structure, while a substantially anisotropic etch process may result in more precisely defined boundaries of the cavity, while nevertheless a certain degree of rounding of corresponding corners may be observed. In this respect, it should be appreciated that corresponding well-established isotropic or anisotropic etch processes may be understood as spatially isotropic or anisotropic processes while, however, an etch rate with respect to different crystallographic orientations within the material of the semiconductor layer 103 may be substantially identical. Thus, using etch techniques having substantially the same etch rate for any crystallographic orientation may provide a high degree of flexibility in adjusting the size and shape of the corresponding cavities, irrespective of whether “spatially” isotropic or anisotropic etch recipes are used. In the example shown in FIG. 1a, it may be assumed that the corresponding cavities may be obtained on the basis of a substantially spatially anisotropic etch process with a certain degree of corner rounding. Next, a selective epitaxial growth process is typically used to deposit the silicon/germanium material, wherein the fraction of germanium may be selected such that a desired degree of lattice mismatch and thus of strain may be obtained. Furthermore, depending on the overall process strategy, prior to or after the selective epitaxial growth process, a dopant species may be introduced in order to form a shallow portion of the drain and source regions 153. Frequently, respective shallow implantation regions in the drain and source regions may be referred to as extensions. Moreover, the dopant species required for forming deep areas of the drain and source regions 153 may be introduced during the selective epitaxial growth process, thereby growing the material 155 as a heavily doped semiconductor alloy. In other cases, the drain and source regions 153 may be completed on the basis of implantation sequences, in which the spacer structure 151 C may act as an implantation mask for adjusting the lateral profile of the drain and source regions 153. Typically, one or more anneal cycles may have to be performed in order to adjust the finally desired dopant profile for the drain and source regions 153 and/or to activate dopants which may have been incorporated by ion implantation, and also repair implantation-induced damage.

During corresponding anneal processes, typically, a significant degree of dopant diffusion may occur, which may depend on the characteristics of the basic semiconductor material and the size of the dopant atoms. For instance, boron is a very small atom and may thus exhibit a pronounced diffusion activity at elevated temperatures. However, the corresponding diffusion may advance in a highly non-uniform manner due to the presence of the silicon/germanium alloy and the preceding manufacturing steps. That is, upon epitaxially growing the material 155 within the cavity, different crystallographic orientations may be present in the exposed surface portions of the cavity, in particular at the rounded corner portions, thereby creating a plurality of stacking defects of the re-grown material 155. Furthermore, due to the lattice mismatch at the interface between the template material of the layer 103 and the newly grown material 155, a more or less pronounced degree of deformation may occur. Furthermore, in general, the increased lattice constant of the material 155, even if re-grown in a strained state, may also contribute to an increased diffusion activity of boron material. For these reasons, it is believed that highly non-uniform PN junctions may be generated since, depending on the local diffusion rate, which may be determined by the defect density, the local strain conditions and the like, the boron species may “penetrate” into the region between the drain and source regions 153 in a spatially highly non-uniform manner.

FIG. 1b schematically illustrates an enlarged view of a corner portion 155A of the material 155 in the vicinity of the PN junction 153P. As previously discussed, due to a plurality of discontinuities 153D, such as stacking defects and the like, the diffusion activity of the boron species may result in “boron pipes” which may therefore contribute to the significantly increased overall length of the PN junction 153P in combination with non-uniform dopant gradients. Thus, due to the variability of the drain and source regions 153, which for instance may affect the parasitic junction capacitance, a corresponding variability in transistor performance may also be observed which may possibly not be compatible with the overall device margins during the entire manufacturing process. Therefore, the per se highly efficient strain-inducing mechanism provided by the material 155 may have to be used in a less pronounced manner in order to obtain increased process margins, while in other conventional solutions the cavity etch process may be performed on the basis of an etch technique, which provides a highly anisotropic etch behavior with respect to a different crystallographic axis of the base material 103. For example, “crystallographically anisotropic” etch techniques are well known in which, for instance, the removal rate in a <111> direction is significantly less compared to other directions, such as <110> or <100> orientations. Thus, applying a respective crystallographically anisotropic etch technique may result in a sigma-like cavity, which may be bordered by the corresponding <111> surfaces. However, while the former approach may not fully exploit the potential of the strain-inducing mechanism provided by the material 155, the latter approach may require specifically designed etch processes thereby reducing the flexibility in adjusting the size and shape of the corresponding cavities and thus of the strain-inducing material 155.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure relates to methods and semiconductor devices in which transistor performance may be improved by reducing non-uniformities of a PN junction of drain and source regions, which may comprise a strain-inducing semiconductor alloy, such as silicon/germanium and the like. For this purpose, the diffusion characteristics of a dopant species, such as boron, may be controlled on the basis of a reduced degree of discontinuities in the vicinity of the PN junction, which may have been created during the preceding manufacturing processes including spatially isotropic or anisotropic etch processes in combination with epitaxial growth techniques for providing the strain-inducing semiconductor alloy. In some illustrative aspects disclosed herein, the degree of non-uniform diffusion of dopant species may be reduced by incorporating an appropriate diffusion hindering species, such a nitrogen, carbon and the like, which may be positioned along a certain distance of the PN junction, in particular at critical locations such as corners and the like of cavities including the strained semiconductor alloy, thereby significantly reducing the locally highly non-uniform diffusion behavior, as may be encountered in conventional devices, which may be formed on the basis of spatially isotropic or anisotropic etch techniques. Consequently, respective boron piping effects may be reduced, thereby contributing to enhanced uniform transistor behavior, for instance with respect to the resulting parasitic capacitance of the PN junctions. In other illustrative aspects disclosed herein, in addition to or alternatively to the above-described approach, the semiconductor base material may be provided with an appropriate crystallographic configuration that results in a reduced amount of lattice discontinuities, such as stacking faults and the like, upon re-growing the strain-inducing semiconductor alloy. For instance, the “vertical” and “horizontal” growth directions may represent crystallographic orientations corresponding to equivalent crystal axes, thereby reducing the amount of lattice mismatch and stacking faults in critical locations, such as corners of a corresponding cavity. Consequently, well-established and flexible spatially isotropic or anisotropic etch techniques may be used, thereby maintaining a high degree of flexibility in appropriately dimensioning the cavity for receiving the strain-inducing semiconductor alloy, while nevertheless enhanced uniformity of the resulting PN junctions may be achieved. Furthermore, both approaches, i.e., the provision of a shallow implant species that may act as a diffusion hindering species and an appropriately selected crystallographic configuration of the semiconductor base material, may be combined, thereby even further enhancing the overall device uniformity. Consequently, reduced performance variability may contribute to further scalability of corresponding process techniques, while at the same time production yield for a given product quality category may be increased.

One illustrative method disclosed herein comprises forming drain and source regions of a field effect transistor in an active semiconductor region, wherein the drain and source regions comprise a strain-inducing semiconductor alloy. The method additionally comprises positioning a diffusion hindering species within the active semiconductor region at a spatially restricted area corresponding to at least a section of a PN junction formed by the drain and source regions. Finally, the method comprises annealing the drain and source regions to activate dopants in the drain and source regions.

A further illustrative method disclosed herein comprises forming a cavity in a crystalline semiconductor region adjacent to a gate electrode structure that is formed above a portion of the crystalline semiconductor region. The crystalline semiconductor region comprises a cubic lattice structure and the cavity defines a length direction corresponding to a first crystallographic direction that is substantially equivalent to a second crystallographic direction defined by a surface orientation of the crystalline semiconductor region. The method further comprises forming a strain-inducing semiconductor alloy in the cavity and forming drain and source regions in the semiconductor region adjacent to the gate electrode structure.

One illustrative semiconductor device disclosed herein comprises a transistor formed above a substrate. The transistor comprises drain and source regions that are formed in an active region on the basis of boron as a dopant species, wherein the drain and source regions form PN junctions with a channel region of the transistor, wherein the drain and source regions include a strain-inducing semiconductor alloy. Furthermore, the transistor comprises a non-doping diffusion hindering species positioned at least along a portion of the PN junctions.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a cross-sectional view of a semiconductor device including an advanced transistor element with a silicon/germanium alloy formed in the drain and source areas, wherein a significant non-uniform boron diffusion may occur, according to conventional strategies;

FIG. 1b schematically illustrates an enlarged view of a critical area with respect to non-uniform boron diffusion of the conventional transistor device of FIG. 1a;

FIGS. 2a-2e schematically illustrate cross-sectional views of a semiconductor device during various manufacturing stages for forming PN junctions of enhanced uniformity on the basis of flexible etch processes and a strain-inducing semiconductor alloy, in accordance with illustrative embodiments;

FIG. 2f schematically illustrates an enlarged view of a critical portion of a PN junction of the device of FIG. 2e;

FIGS. 3a-3b schematically illustrate a top view and a cross-sectional view, respectively, of a transistor including a semiconductor base material in which crystallographic planes in the horizontal and vertical directions may be equivalent in order to reduce lattice defects upon re-growing a strain-inducing semiconductor alloy, according to illustrative embodiments;

FIGS. 3c-3d schematically illustrate a top view and a cross-sectional view, respectively, wherein different types of crystallographic planes may be used, according to still further illustrative embodiments;

FIGS. 3e-3f schematically illustrate cross-sectional views at various manufacturing stages in forming a strain-inducing semiconductor alloy on the basis of the principles discussed with reference to FIGS. 3a-3d so as to reduce diffusion non-uniformities of a dopant species, such as boron, according to still further illustrative embodiments; and

FIG. 4 schematically illustrates a transistor having a strain-inducing semiconductor alloy and PN junctions with enhanced uniformity, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure provides techniques and semiconductor devices in which enhanced uniformity of PN junctions in transistors comprising a strain-inducing semiconductor alloy in the drain and source regions may be accomplished by reducing the degree of out-diffusion of the dopant species, such as boron, while not unduly reducing the flexibility in forming an appropriate cavity prior to the selective epitaxial growth process for forming the strain-inducing semiconductor alloy. For this purpose, in some illustrative embodiments, at least critical portions of the PN junctions may be “embedded” into a diffusion hindering “environment” which may result in a reduced diffusivity of the dopant species. For instance, an appropriate diffusion hindering species, such as nitrogen, carbon, fluorine and the like, may be appropriately positioned in the vicinity of at least critical portions of the PN junctions in order to reduce any “piping” effects, which may conventionally be observed in sophisticated P-channel transistors using a boron dopant species. Consequently, a reduced variability of the transistor characteristics may be accomplished, while generally a tendency to enhance performance may be obtained, since, typically, at least the parasitic junction capacitance may be reduced due to the “straightening” effect of the diffusion hindering species during any heat treatments, which may typically result in dopant diffusion. Since, typically, the diffusion hindering species may be provided in the form of a “non-doping” species, a significant influence on the electronic characteristics at the PN junction, except for the enhanced uniformity of the shape and thus of the dopant gradient, may be avoided, thereby also contributing to enhanced overall uniformity of the transistor characteristics.

In other illustrative embodiments, in addition to or alternatively to the above-described techniques, the generation of lattice defects may be reduced while nevertheless maintaining a high degree of flexibility in forming the cavity for receiving the strain-inducing semiconductor alloy in that the conditions during the selective epitaxial growth process may be improved by providing more precisely defined template planes in the cavity, which may, for instance, be formed on the basis of a spatially anisotropic etch process. That is, in this case, substantially vertical and substantially horizontal surfaces of the cavity may represent equivalent crystallographic planes so that the corresponding vertical and horizontal growth of the strain-inducing semiconductor alloy may occur with a reduced degree of lattice mismatch even at critical device areas, such as corners of the cavity, in which typically a plurality of different crystallographic axes may be present. Furthermore, by combining enhanced growth conditions during the selective epitaxial process and by using a diffusion hindering species, an even further enhanced overall uniformity of the PN junctions may be accomplished. Thus, compared to conventional techniques, transistor performance variability may be reduced or enhanced flexibility with respect to using well-established etch techniques may be maintained, when compared to conventional crystallographically anisotropic etch techniques which may frequently be used in order to reduce the number of lattice defects upon selectively growing a strain-inducing semiconductor alloy.

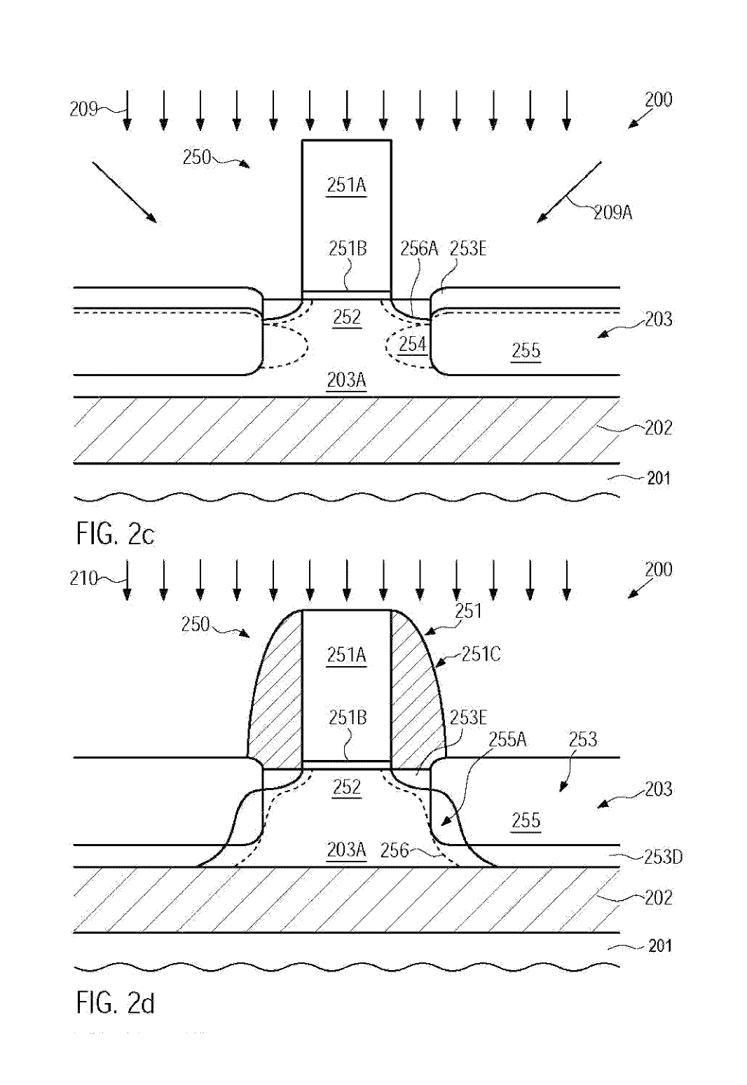

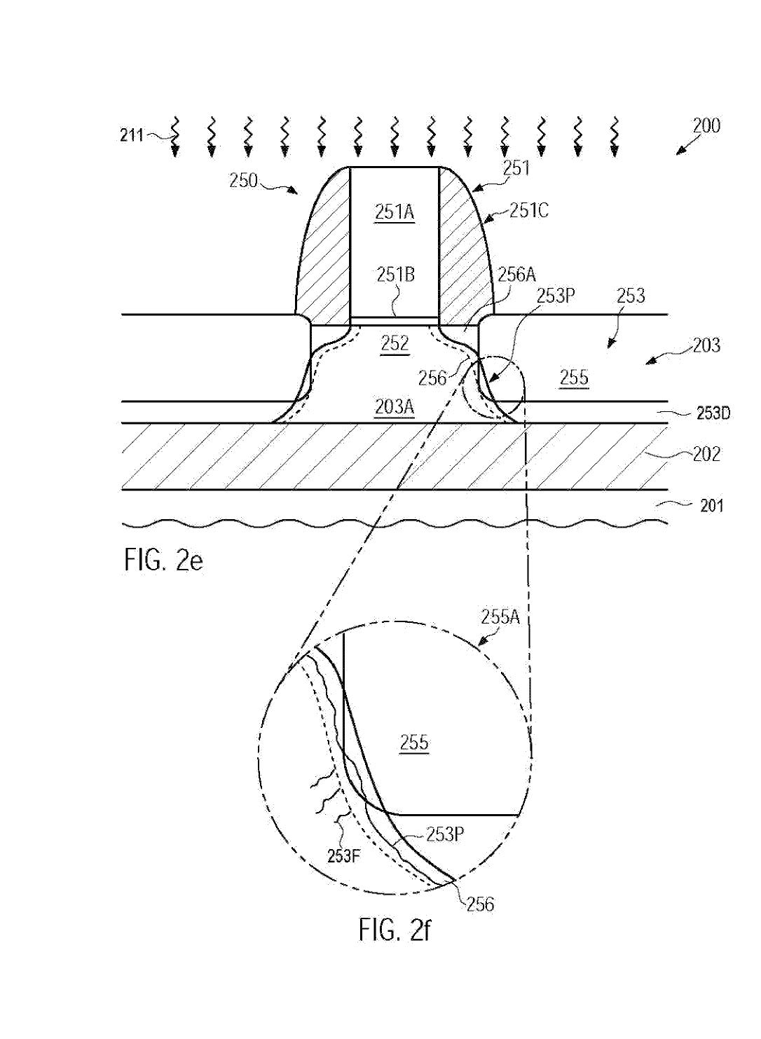

FIG. 2a schematically illustrates a cross-sectional view of a semiconductor device 200 comprising a substrate 201, above which may be formed a semiconductor layer 203. The substrate 201 may represent any appropriate carrier material for forming thereabove the semiconductor layer 203. In the embodiment shown, a buried insulating layer 202, such as an oxide layer, a silicon nitride layer and the like may be positioned between the substrate 201 and the semiconductor layer 203, thereby defining an SOI configuration. It should be appreciated that the principles disclosed herein are highly advantageous in the context of SOI transistors, in which generally the advantage of a reduced PN junction capacitance may be obtained due to the fact that the PN junction may extend down to the buried insulating layer 202. However, enhanced uniformity of the corresponding transistor PN junctions may also be advantageous with respect to bulk transistor configurations. Thus, in other illustrative embodiments, the semiconductor device 200 may be based on a bulk configuration or may comprise in other device areas a bulk configuration, if deemed appropriate for the overall performance of the semiconductor device 200. In the embodiment shown, a portion of the semiconductor layer 203 may represent an active region, which may also be referred to as active region 203A. It should be appreciated that the active region 203A may receive a plurality of transistor elements of the same conductivity type or may include a single transistor, depending on the overall device configuration. For example, in densely packed device regions, such as static RAM areas, a plurality of transistor elements of the same conductivity type may be provided within a single active region, wherein at least some of these transistor elements may receive a strain-inducing semiconductor alloy. In the embodiment shown, the active region 203A may be configured to form therein and thereabove a P-channel transistor. In other cases, N-channel transistors may be considered when a corresponding diffusion activity of an N-type dopant species may be considered inappropriate. Furthermore, a transistor 250 may be provided in an early manufacturing stage, wherein a gate electrode 251A may be formed above a channel region 252 with an intermediate gate insulation layer 251B. It should be appreciated that the gate electrode 251A may be comprised of any appropriate material in this manufacturing stage, such as polycrystalline silicon and the like, wherein a portion or the entire gate electrode 251A may be replaced by a material of enhanced conductivity, depending on the overall process and device requirements. Similarly, the gate insulation layer 251B may be comprised of various materials, such as silicon dioxide-based materials, silicon nitride and the like, wherein, in combination with such “conventional” dielectrics or instead of these materials, high-k dielectric materials may also be used, such as hafnium oxide, zirconium oxide and the like. Generally, a high-k dielectric material is to be understood as a material having a dielectric constant of 10.0 or greater. The gate electrode 251A may be encapsulated by a cap layer 204 and sidewall spacers 205, which may be comprised of silicon nitride or any other appropriate material that may act as a mask during an etch process 207 in order to provide recesses or cavities 206 adjacent to the gate electrode 251A, i.e., the sidewall spacers 205.

The semiconductor device 200 as shown in FIG. 2a may be formed on the basis of the following processes. After forming the active region 203A, for instance by providing appropriate isolation structures (not shown), which may involve well-established manufacturing techniques, the gate electrode 251A and the gate insulation layer 251B may be formed, for instance on the basis of process techniques as previously described with reference to the device 100. During this manufacturing sequence, the cap layer 204 may also be patterned, for instance by forming a respective silicon nitride layer on a corresponding gate electrode material. Next, the sidewall spacers 205 may be formed by depositing an appropriate material, such as a silicon nitride material, and anisotropically etching the material above the active region 203A, while covering the silicon nitride material in other device areas in which the formation of spacer elements may not be desired. Next, the etch process 207 may be performed on the basis of appropriately selected etch parameters in order to adjust the desired size and shape of the cavities 206. The process 207 may represent an etch process in which the removal rate may be substantially independent from any crystallographic orientations of the material of the layer 203. That is, the process parameters of the etch process 207 may be selected with respect to a spatial degree of isotropy or anisotropy while the crystallographic orientations of the semiconductor material 203 may not significantly affect the removal rate. That is, well-established plasma-based etch techniques may be used in which the spatial degree of anisotropy or isotropy may by adjusted by selecting parameters, such as bias power, pressure, temperature and the like, in combination with specific organic polymer species, which may more or less protect respective sidewall portions during the etch process, thereby allowing a substantially vertical progression of the etch front. In this respect, it should be appreciated that any positional statements, such as horizontal, vertical and the like, are to be considered with respect to a reference plane, such as an interface 202S between the buried insulating layer 202 and the semiconductor layer 203. In this sense, a horizontal direction is to be considered as a direction substantially parallel to the interface 202S, while a vertical direction is to be understood as a direction substantially perpendicular to the interface 202S.

Thus, in the embodiment shown, the etch process 207 may represent a substantially anisotropic etch process since a significant under-etching of the spacer structure 205 may be considered inappropriate for the device 200. In other embodiments, a more isotropic behavior may be adjusted by using appropriate parameters in the process 207, at least during a certain phase of the etch process, when a more rounded shape of the cavity 206 is desired.

In some illustrative embodiments, prior to forming the spacer structure 205, one or more implantation processes may be performed in order to introduce a dopant species and/or a diffusion hindering species, depending on the manufacturing strategy. For instance, in one illustrative embodiment, the dopant species for forming drain and source extension regions 253E may be introduced, for instance in the form of boron or boron fluoride ions, in accordance with the requirements of the characteristics of the transistor 250. In one illustrative embodiment, a diffusion hindering species 256A may additionally be introduced in a separate ion implantation step when an “embedding” of the drain and source extension regions 253E may be considered advantageous for enhancing the overall uniformity of the PN junctions of the transistor 250. For example, even if the occurrence of lattice defects in the vicinity of the channel region 252 may be less pronounced, a restriction of the diffusion activity of, for instance, boron may nevertheless be advantageous in view of more precisely controlling the finally obtained channel length, and thus the resulting overlap capacitance, during subsequent heat treatments of the device 200. Thus, the incorporation of the diffusion hindering species 256A, for instance in the form of nitrogen, carbon, fluorine and the like, may thus contribute to enhanced uniformity of the finally obtained transistor characteristics. For this purpose, a specifically designed implantation step may be performed so as to position the species 256A around the PN junction 253P such that, during a subsequent diffusion activity of the dopant species, the additional diffusion hindering species 256A may provide an environment in which the average diffusion path length may be less compared to an area defined or delineated by the diffusion hindering species 256A. In this context, it should be appreciated that an area defined by the diffusion hindering species 256A may be considered as an area in which the concentration of the diffusion hindering species drops to two orders of magnitude compared to a maximum concentration. That is, any area outside of a “diffusion hindering area” may be defined as including the diffusion hindering species with a concentration that is less than two orders of magnitude of the maximum concentration.

The diffusion hindering species 256A may be positioned with an appropriate concentration by selecting appropriate process parameters, such as implantation energy and dose, which may readily be determined on the basis of well-established simulation programs, experience, test runs and the like. For instance, carbon or nitrogen may be incorporated with a concentration of approximately 10¹⁶-10¹⁹ atoms per cm³ or even higher, depending on the concentration of the boron species in the extension regions 253E. This may be accomplished by an implantation dose of approximately 10¹⁴-10¹⁶ ions per cm² while using implantation energies from several keV to several tens of keV.

In still other illustrative embodiments, the diffusion hindering species 256A may be incorporated in this manufacturing stage without forming the extension regions 253E, which may be formed in a later manufacturing stage, depending on the overall process strategy.

FIG. 2b schematically illustrates the semiconductor device 200 according to further illustrative embodiments in which a diffusion hindering species 256 may be introduced by an ion implantation process 208 prior to filling the cavities 206 by a strain-inducing semiconductor alloy. In the embodiment shown, the diffusion hindering species 256A may have also been incorporated while the extension regions 253E may be formed or not, depending on the overall strategy, as explained above. During the implantation process 208, an appropriate implantation species, such as nitrogen, carbon, fluorine and the like, may be introduced on the basis of specifically selected implantation parameters wherein also, as illustrated, a certain tilt angle may be used to provide the desired shape of the area defined by the species 256. Introducing the diffusion hindering species in this manufacturing stage may be advantageous with respect to process strategies in which the dopant species of deep drain and source areas may be incorporated on the basis of the selective epitaxial growth process to be performed in a later stage so as to fill the cavities 206. In this case, the region 256 may be formed in an efficient manner during the implantation process 208, while avoiding undue lattice damage in the strain-inducing semiconductor material to be formed in the cavities 206, while, also, due to a moderately low implantation dose, significant damage of exposed surface portions of the cavity 206 may be avoided. In other cases, an appropriate anneal process, possibly as a preconditioning step prior to the selective epitaxial growth process, may be performed in order to reduce lattice damage created by the implantation process 208, if the corresponding damage is considered inappropriate for the subsequent selective epitaxial growth process. With respect to selecting appropriate implantation parameters of the process 208, the same criteria apply as previously explained with reference to FIG. 2a.

FIG. 2c schematically illustrates the semiconductor device 200 in a further advanced manufacturing stage according to other illustrative embodiments. As illustrated, a strain-inducing semiconductor alloy 255 may be formed in the cavities 206, which may be accomplished by using well-established selective epitaxial growth techniques in which the deposition parameters are adjusted in such a manner that a significant growth of a desired semiconductor alloy, such as silicon/germanium, silicon/carbon and the like, may be obtained at exposed crystalline surface portions, while substantially avoiding any deposition of the semiconductor alloy on other surface areas, such as the dielectric materials of the spacers 205 and the cap layer 204 (FIG. 2a). Furthermore, in the embodiments shown, the extension regions 253E may be formed during an implantation process 209 if the regions 253E may not have been formed in an earlier manufacturing stage. That is, after the removal of the spacer elements 205 and the cap layer 204 (FIG. 2a) and forming a corresponding offset spacer (not shown), if required, a dopant species, such as boron, boron difluoride and the like, may be incorporated during the implantation process 209, wherein, in some illustrative embodiments, an additional implantation step may be applied in order to incorporate a diffusion hindering species to form the region 256A, if required. Moreover, specific transistor characteristics may be adjusted by providing a counter-doped region 254, which may also be referred to as a halo region, as is also previously explained with reference to the device 100. For this purpose, a tilted implantation process 209A may be performed to introduce an N-type dopant species, if the transistor 250 is to represent a P-channel transistor.

FIG. 2d schematically illustrates the semiconductor device 200 in a further advanced manufacturing stage. As shown, a gate electrode structure 251 including the gate electrode 251A, the gate insulation layer 251B and a spacer structure 251C may be provided in accordance with the overall device requirements. That is, the spacer structure 251C may have an appropriate width as required for the further processing of the device 200. For example, in the embodiment shown, the spacer structure 251C may, in combination with the gate electrode 251A, be used as an implantation mask for forming deep drain and source areas 253D which, in combination with the extension regions 253E, may define drain and source regions 253 of the transistor 250. It should be appreciated that the spacer structure 251C may include several individual spacer elements if a more complex lateral dopant profile for the drain and source regions 253 is required. In other cases, the spacer structure 251C may represent a mask for a silicidation process to be performed in a later manufacturing stage when the drain and source regions 253 are to be formed on the basis of a dopant species incorporated during the epitaxial growth process for forming the strain-inducing semiconductor alloy 255. Thus, in some illustrative embodiments, the dopant species for defining the deep drain and source areas 253D may at least partially be embedded in the diffusion hindering species 256, thereby providing more uniform diffusion behavior of the dopant species during a subsequent anneal process. In other illustrative embodiments, in addition to any implantation processes that may be used for forming the deep drain and source areas 253D, a further implantation process 210 may be performed so as to position the diffusion hindering species 256 at least at critical portions of the active region 203A with respect to lattice defects, as previously explained. That is, the diffusion hindering species 256A may or may not have been incorporated during the preceding manufacturing sequence, depending on the overall process strategy, while, however, the species 256 may be introduced during the process 210 when a respective implantation in an earlier manufacturing stage, for instance as shown in FIG. 2b, may not have been performed. Consequently, during the process 210, appropriate process parameters with respect to dose, energy and tilt angle may be selected, for instance on the basis of well-established simulation programs, in order to appropriately position the diffusion hindering species 256. In particular, the implantation parameters, for instance the tilt angle during the process 210, may be selected so that the diffusion hindering species 256 may be provided at a corner portion 255A, at which an enhanced defect density may be created during the preceding manufacturing sequence, as previously explained.

FIG. 2e schematically illustrates the semiconductor device 200 during an anneal process 211 during which implantation-induced damage may be cured to a certain degree, while the finally desired profile of the drain and source regions 253 may also be adjusted due to the thermally induced diffusion of the corresponding dopant species, such as boron. Furthermore, if the drain and source regions 253, at least the deep drain and source areas 253D, may have been formed on the basis of an implantation process, the corresponding lattice damage may also be re-crystallized during the anneal process 211. As previously explained, a significant diffusion of light and small atoms may occur, such as boron, wherein the diffusivity may locally vary according to respective lattice defects and lattice mismatch obtained during the formation of the strain-inducing semiconductor alloy 255. Since the drain and source regions 253, after implantation or deposition, are embedded within the diffusion hindering species 256, a restriction of the diffusion activity may occur, thereby also reducing increased non-uniformities, in particular in critical device areas, such as the corner 255A.

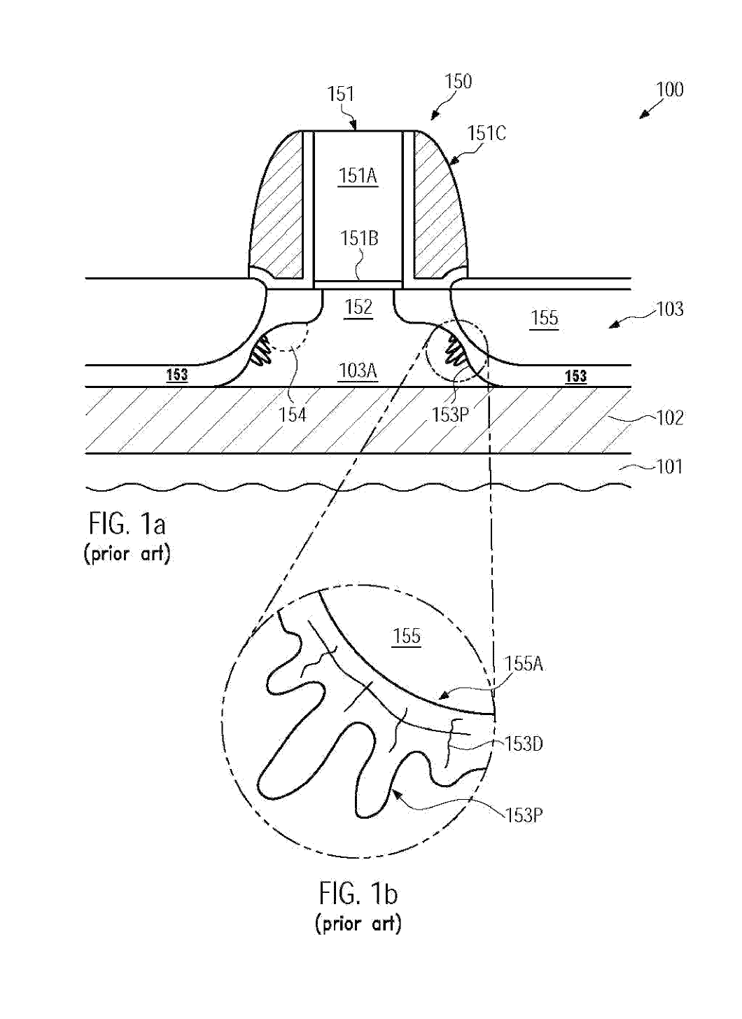

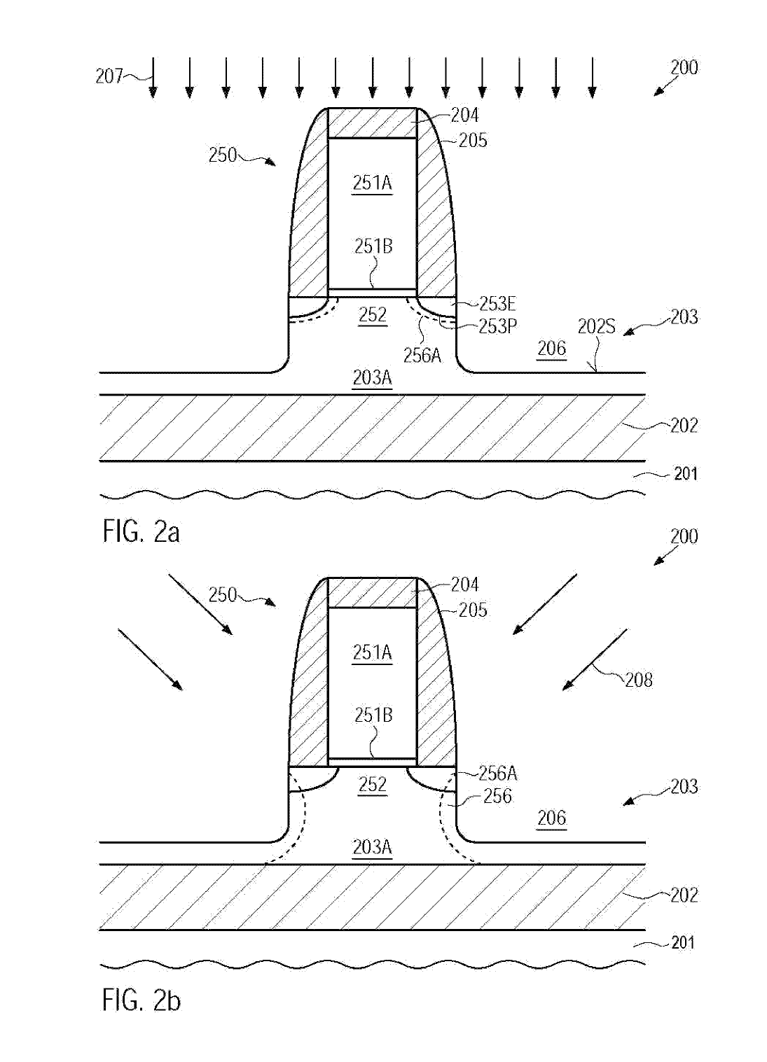

FIG. 2f schematically illustrates an enlarged view of the critical area 255A as shown in FIG. 2E. As illustrated, a moderate high degree of lattice defects 253F, for instance in the form of stacking faults and the like, may be present in the corner portion 255A, which would conventionally result in a highly non-uniform diffusion behavior of the dopant species, such as boron, thereby creating “dopant pipes” that may contribute to a high degree of variability of the junction capacitance, as previously explained. According to the diffusion hindering species 256, the effect of the discontinuities 253F on the diffusion activity may be significantly reduced, thereby forming the PN junction 253P with less pronounced dopant pipes so that the PN junction 253P may be substantially confined within the area formed by the diffusion hindering species 256. Due to the “smoothing” of the PN junction 253P compared to conventional devices (see FIG. 1b), the resulting junction capacitance may be less and may also exhibit a reduced tolerance, thereby contributing to an improvement of overall device characteristics while also reducing transistor variability in complex semiconductor devices. For example, in densely packed static RAM areas, operational stability of memory areas may be enhanced due to increasing uniformity of the diffusion behavior of the dopant species, such as boron. Similarly, as previously explained, by providing the diffusion hindering species 256A at the channel region 252, the corresponding overlap capacitance may also be adjusted with enhanced uniformity, which may also contribute to overall device performance and operational stability. It should be appreciated that the diffusion hindering species 256A, 256 may be provided along the entire length of the PN junction 253P, as is for instance shown in FIG. 2e, while, in other embodiments, the species 256 may be provided at critical areas, such as the corner portion 255A.

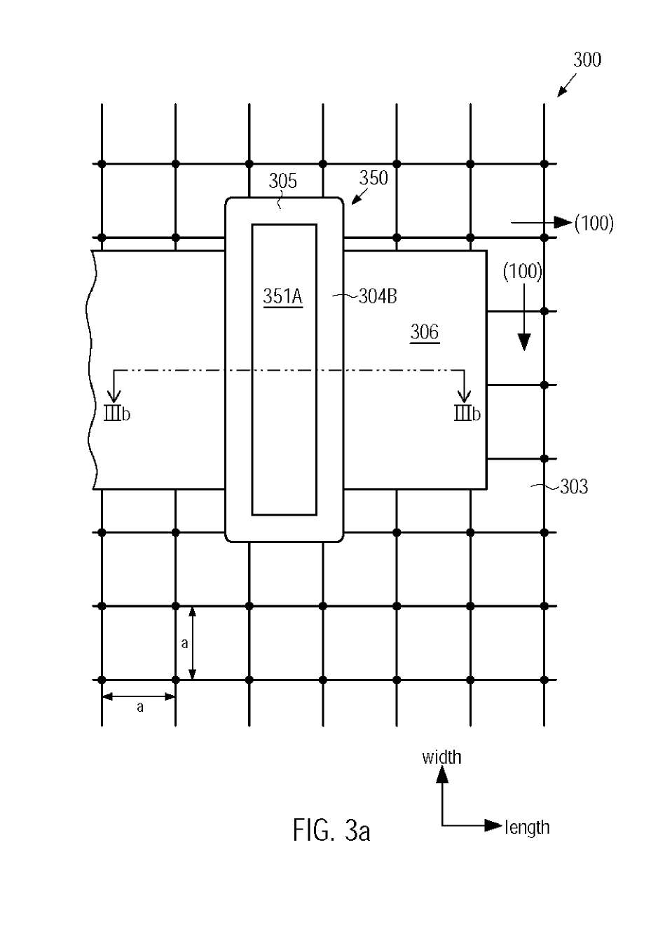

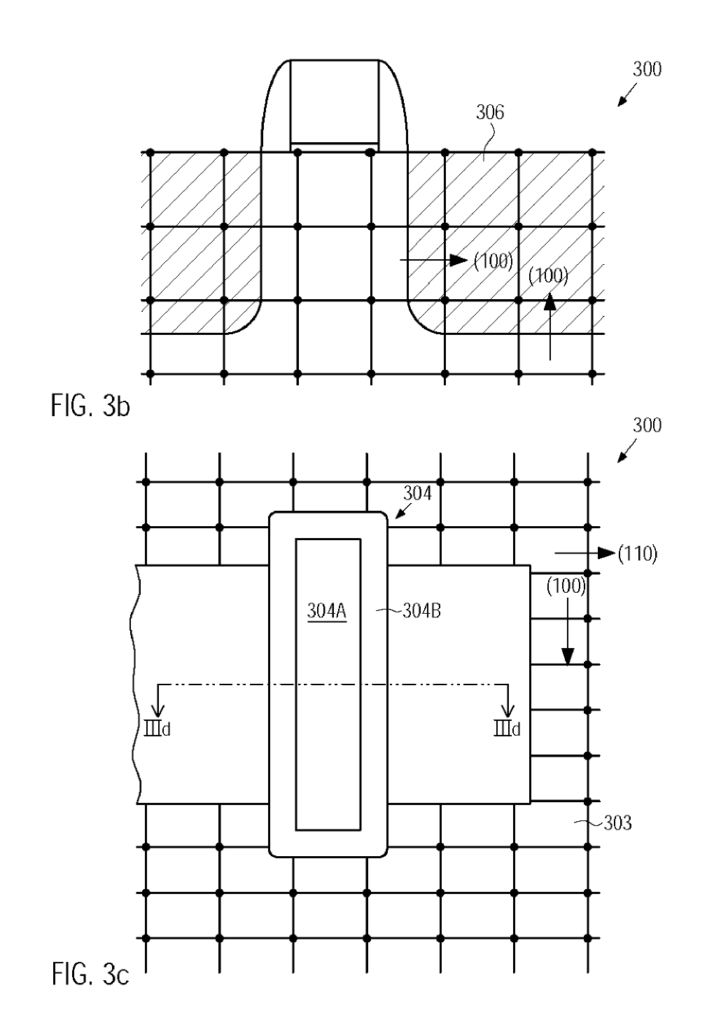

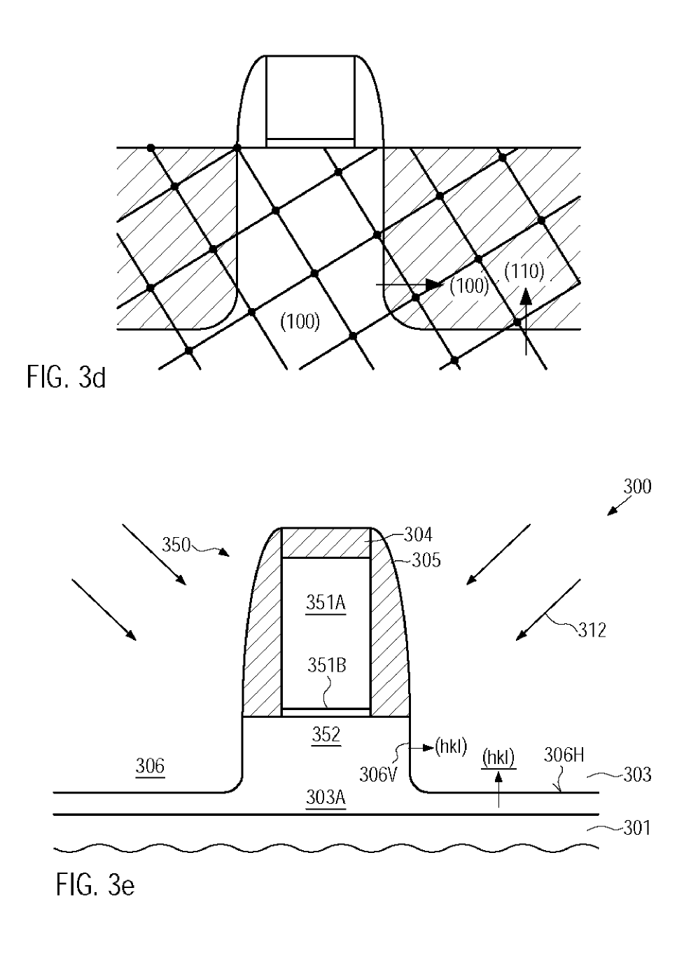

With reference to FIGS. 3a-3f, further illustrative embodiments will now be described in more detail in which the generation of lattice defects may be reduced by appropriately selecting the crystallographic configuration of a base semiconductor material.

FIG. 3a schematically illustrates a top view of a semiconductor device 300 comprising a transistor 350, which may be formed on a semiconductor layer 303, such as a silicon layer and the like, which may have a cubic lattice structure. As is well known, in conventional techniques, the basic silicon layer may be provided with a (100) surface orientation, wherein the transistor length direction, i.e., in FIG. 3a, the horizontal direction, is oriented along a <110> direction. In this respect, it should be appreciated that crystallographic orientations are typically expressed by so-called Miller indices which describe the position and orientation of a crystal plane by giving the coordinates of three non-collinear atoms lying in the plane. This may conveniently be expressed by the Miller indices which are determined as follows:
Intercepts of three basis axes are to be determined in terms of the lattice constant of the semiconductor crystal under consideration; and
The reciprocals of these numbers are taken and are reduced to the smallest three integers having the same ratio, wherein the respective results are written in parentheses so as to indicate a specific crystalline plane. For convenience, planes equivalent by symmetry are herein denoted also by the same Miller indices. For instance, a (100), a (010), a (001) plane and the like are physically equivalent and may commonly be indicated as (100) plane.

Similarly, crystallographic directions may also be expressed on the basis of Miller indices representing the set of smallest integers having the same ratios as the components of a respective vector in the desired direction. For example, in crystals having a cubic lattice structure, such as a silicon crystal, a crystallographic direction classified by a certain set of Miller indices is perpendicular to the plane represented by the same set of Miller indices.

Thus, for the standard crystallographic orientation of a silicon layer, such as the silicon layer 103 in FIG. 1a, the respective surface is a (100) surface while the transistor length direction and the transistor width direction are aligned to <110> directions. Consequently, for a crystalline material that has to be grown in a cavity including vertical and horizontal surface portions, the growth directions may represent different crystallographic orientations, i.e., a <100> and a <110> direction, which may result in increased stacking faults during the selective epitaxial growth process. According to the embodiments described with reference to FIGS. 3a-3f, however, the semiconductor layer 303 may have an appropriate configuration with respect to its crystallographic orientation such that the transistor 350, which may include, in the manufacturing stage shown, a gate electrode 351A, a gate insulation layer (not shown) and a sidewall spacer structure 305 is aligned to the crystallographic directions of the semiconductor layer 303 so as to present substantially the same, i.e., equivalent, crystalline growth directions when growing a semiconductor alloy in a recess 306. For example, the semiconductor layer 303 may represent a silicon-based crystalline layer having a (100) surface orientation wherein the length direction is aligned along the <100> direction. That is, with respect to conventional designs, the length direction is rotated by 45 degrees which may, for instance, be accomplished by correspondingly rotating a silicon wafer with respect to the conventional configuration, wherein typically a respective notch may indicate the <110> direction.

FIG. 3b schematically illustrates a cross-sectional view of the device 300 as shown in FIG. 3a, wherein schematically the cavity 306 is illustrated as a hatched area, which defines horizontal and vertical growth directions, which are specified by the same Miller indices, i.e., the respective template surfaces for the horizontal and vertical growth process are (100) surfaces, thereby reducing respective stacking faults which may be created in the conventional technique upon growing a strain-inducing semiconductor alloy, such as a silicon/germanium alloy.

FIG. 3c schematically illustrates the semiconductor device 300 in accordance with further illustrative embodiments in which the semiconductor layer 303 may be provided so as to exhibit a (110) surface orientation so that, for a cubic lattice structure, such as silicon, a <100> direction and a <110> direction may be present with an angle offset of 90 degrees, as indicated by the corresponding arrows in FIG. 3c.

FIG. 3d schematically illustrates a cross-sectional view of the device of FIG. 3c wherein a (100) plane is provided in the drawing plane of FIG. 3d while the respective growth directions within the cavity 306 are based on respective <110> direction. Thus, as explained above, upon selectively growing a strain-inducing semiconductor alloy, such as silicon/germanium and the like, a reduced number of stacking faults may be created, thereby providing advantages with respect to the diffusion behavior of a light dopant species, such as boron, as discussed above.

FIG. 3e schematically illustrates the semiconductor device 300 during a corresponding epitaxial growth process 312 in order to fill in a strain-inducing semiconductor alloy in the recesses 306. During the process 312, the gate electrode 351A and a gate insulation layer 351B may be encapsulated by a cap layer 304 and a sidewall spacer 305. Due to the specific crystallographic configuration of the semiconductor layer 303, substantially equivalent crystal planes, as indicated by the Miller indices (hkl), may be encountered for substantially vertical surfaces 306V and substantially horizontal surfaces 306H. Consequently, a reduced degree of lattice discontinuities may be created during the growth process 312.

FIG. 3f schematically illustrates the semiconductor device 300 with a strain-inducing semiconductor alloy 355, which may represent a silicon/germanium material when the transistor 350 may represent a P-channel transistor. Furthermore, in the embodiment shown, additionally, a diffusion hindering species 356, for instance in the form of nitrogen, carbon, fluorine and the like, may be provided to further reduce diffusion non-uniformities during subsequent anneal processes. In one illustrative embodiment, the diffusion hindering material 356 may be spatially restricted to a critical portion 355A, at which per se an increased amount of lattice defects may be generated during the preceding growth process 312. However, due to the matching growth directions <hkl> (see FIG. 3e), the number and the size of the corresponding lattice defects 353D may be reduced, thereby requiring a reduced concentration and/or local extension of the diffusion hindering species 356. For example, the diffusion hindering species 356 may be introduced, for instance, prior to the epitaxial growth process 312 on the basis of appropriate implantation parameters, for instance with respect to dose, energy and tilt angle, in order to provide the species 356 with a moderately low concentration and at a desired position. In other cases, the diffusion hindering species 356 may be incorporated by ion implantation during an implantation sequence in which counter doped regions (not shown) also may be formed, as is also previously explained with reference to the devices 100 and 200. In other illustrative embodiments, the diffusion hindering species 356 may be incorporated so as to extend substantially along the entire length of a PN junction still to be formed, similarly as is shown in FIG. 2e.

Consequently, enhanced uniformity of the resulting PN junction may be accomplished by reducing the amounts of defects 353D, wherein, in further illustrative embodiments, additionally, the diffusion hindering species 356 may be provided, at least at critical device areas, however, at a reduced concentration, which may enhance overall transistor uniformity while even further reducing any effect of the diffusion hindering species in view of the overall device characteristics.

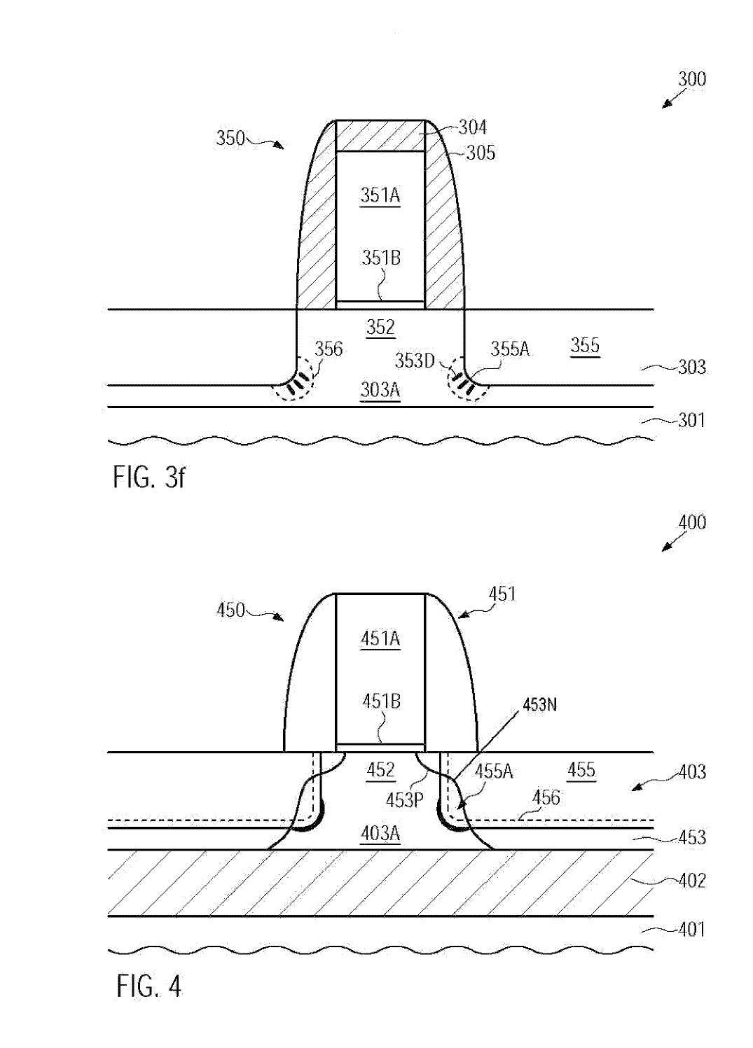

With reference to FIG. 4, further illustrative embodiments will now be described in which a diffusion hindering species may be incorporated, at least partially, during the selective epitaxial growth process.

FIG. 4 schematically illustrates a cross-sectional view of a semiconductor device 400 including a substrate 401, a semiconductor layer 403 and, optionally, a buried insulating layer 402. Furthermore, a transistor 450 may be formed in and above a portion of the semiconductor layer 403 and may comprise a gate electrode structure 451, drain and source regions 453, in which a strain-inducing semiconductor material 455 may be provided. For example, the transistor 450 may represent a P-channel transistor comprising a silicon/germanium alloy as the semiconductor alloy 455. Moreover, drain and source regions may be formed in the semiconductor layer 403, thereby defining a PN junction 453P, which may have a portion 453N positioned within the strain-inducing material 455. Furthermore, a diffusion hindering species 456 may be provided at an interface between the material 455 and material of the semiconductor layer 403. For example, the diffusion hindering material may be incorporated in the form of carbon, nitrogen and the like. Consequently, upon performing an anneal process, the diffusion hindering material 456 may appropriately reduce the overall diffusion activity of the dopant species of the drain and source regions 453 at a critical corner portion 455A, thereby contributing to enhanced uniformity of the respective portion 453N of the PN junction 453P.

The semiconductor device 400 as shown in FIG. 4 may be formed on the basis of similar process techniques as previously described wherein, however, during a corresponding epitaxial growth process, the diffusion hindering species 456 may be incorporated, for instance in the form of nitrogen and the like, which may be accomplished by adding a respective precursor component to the deposition ambient. Thereafter, the supply of the diffusion hindering species into the deposition ambient may be discontinued and the growth process may be continued on the basis of well-established process parameters for obtaining the material 455. Thereafter, the further processing may be continued by forming the drain and source regions 453 and performing an anneal sequence in order to obtain the finally desired dopant profile, wherein the species 456 may provide enhanced overall uniformity, as is also previously discussed.

As a result, the present disclosure relates to techniques and semiconductor devices in which transistor characteristics, such as behavior of P-channel transistors, may be enhanced by providing appropriate conditions during respective anneal processes to reduce diffusion related non-uniformities at the PN junction, in particular at critical portions, which may exhibit an increased defect density due to the preceding formation of a strain-inducing semiconductor alloy. For this purpose, a diffusion hindering species may appropriately be positioned at the PN junction so as to provide a neighborhood for the dopant species, such as boron, which may result in a less pronounced diffusion activity. In other cases, the defect density at critical device portions may be reduced by appropriately selecting vertical and horizontal growth directions in a respective cavity, which may be assisted by the introduction of a diffusion hindering species which, however, may be provided with a reduced concentration, thereby also reducing any effects of the diffusion hindering species on the overall transistor characteristics. Due to the principles disclosed herein, the process sequence for forming cavities adjacent to the gate electrode structure may be performed on the basis of crystallographically isotropic etch techniques, such as plasma-based etch processes with spatial anisotropy or isotropy, thereby providing enhanced flexibility in adjusting the size and shape of the strain-inducing semiconductor alloy.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming drain and source regions of a field effect transistor in an active semiconductor region, said drain and source regions comprising a strain-inducing semiconductor alloy;
positioning a diffusion hindering species within said active semiconductor region at a spatially restricted area corresponding to at least a section of a PN junction formed by said drain and source regions; and
annealing said drain and source regions to activate dopants in said drain and source regions.

2. The method of claim 1, wherein said diffusion hindering species comprises at least one of carbon and nitrogen.

3. The method of claim 1, wherein said diffusion hindering species is positioned in said locally restricted area by performing an implantation process.

4. The method of claim 3, wherein said implantation process is performed prior to forming at least deep drain and source areas of said drain and source regions.

5. The method of claim 1, wherein said spatially restricted area is formed to extend along substantially the entire length of said PN junction.

6. The method of claim 1, further comprising forming said strain-inducing semiconductor alloy by forming a cavity in said drain and source regions and filling said semiconductor alloy into said cavity by performing a selective epitaxial growth process.

7. The method of claim 6, wherein forming said cavity comprises performing an etch process having a substantially isotropic etch behavior with respect to crystallographic axes of material of said active semiconductor region.

8. The method of claim 7, wherein said etch process includes at least partially a spatially isotropic etch behavior.

9. The method of claim 7, wherein said etch process includes at least partially a spatially anisotropic etch behavior.

10. The method of claim 6, wherein at least a portion of said diffusion hindering species is positioned when performing said selective epitaxial growth process.

11. The method of claim 1, wherein said semiconductor alloy is comprised of silicon and germanium.

12. The method of claim 1, wherein said active semiconductor region is formed on a buried insulating layer.

13. A method, comprising:
forming a cavity in a crystalline semiconductor region adjacent to a gate electrode structure formed above a portion of said crystalline semiconductor region, said crystalline semiconductor region comprising a cubic lattice structure, said cavity defining a length direction corresponding to a first crystallographic direction that is substantially equivalent to a second crystallographic direction defined by a surface orientation of said crystalline semiconductor region;
forming a strain-inducing semiconductor alloy in said cavity; and
forming drain and source regions in said semiconductor region adjacent to said gate electrode structure.

14. The method of claim 13, wherein forming said cavity comprises performing an etch process having a substantially isotropic etch behavior with respect to crystallographic orientations of material of said semiconductor region.

15. The method of claim 13, further comprising positioning a diffusion hindering species at least in the vicinity of a section of a PN junction formed by said drain and source regions with an intermediate portion of said semiconductor region.

16. The method of claim 15, wherein said diffusion hindering species is positioned by performing an implantation process.

17. The method of claim 16, wherein said implantation process is performed separately to one or more further implantation processes performed so as to introduce a dopant species to form said drain and source regions.

18. The method of claim 17, wherein said diffusion hindering species comprises at least one of carbon, nitrogen and fluorine.

19. The method of claim 13, wherein said strain-inducing semiconductor alloy comprises silicon and germanium.

20. A semiconductor device, comprising:
a transistor formed above a substrate, said transistor comprising:
drain and source regions formed in an active region on the basis of boron as a dopant species, said drain and source regions forming PN junctions with a channel region of said transistor, said drain and source regions including a strain-inducing semiconductor alloy, and
a non-doping diffusion hindering species positioned at least along a portion of said PN junctions.

21. The semiconductor device of claim 20, wherein said non-doping diffusion hindering species comprises at least one of carbon and nitrogen.

22. The semiconductor device of claim 20, wherein a concentration of said diffusion hindering species in said channel region is at least two orders of magnitude less than a maximum concentration of said diffusion hindering species.
